(19) United States
(12) Patent Application Publication
(10) Pub. No.: US 2021/0272840 A1
(43) Pub. Date: Sep. 2, 2021

(54) METHOD OF MANUFACTURING SEMICONDUCTOR DEVICE

(71) Applicant: Tokyo Electron Limited, Tokyo (JP)

(72) Inventors: Tatsuya YAMAGUCHI, Nirasaki City (JP); Syuji NOZAWA, Nirasaki City (JP)

(21) Appl. No.: 17/183,814

(22) Filed: Feb. 24, 2021

(30) Foreign Application Priority Data
Feb. 28, 2020 (JP) 2020-033591

(51) Int. Cl. H01L 21/764; H01L 21/02

(52) U.S. Cl. CPC H01L 21/764; H01L 21/02244; H01L 21/02118

(57) ABSTRACT

A method of manufacturing a semiconductor device includes a first deposition process, a second deposition process, an oxidation process, and a desorption process. In the first deposition process, a thermally decomposable organic material on a substrate in which a recess is formed, is deposited. In the second deposition process, a metal layer is deposited on the organic material by sputtering, which uses a target containing metal. In the oxidation process, the metal layer is oxidized. In the desorption process, an air gap is formed between the oxidized metal layer and the recess by heating the substrate at a predetermined temperature to thermally decompose the organic material to desorb the organic material under the oxidized metal layer through the oxidized metal layer.

### CROSS-REFERENCE TO RELATED APPLICATION

This application is based upon and claims the benefit of priority from Japanese Patent Application No. 2020-033591, filed on Feb. 28, 2020, the entire contents of which are incorporated herein by reference.

### TECHNICAL FIELD

The present disclosure relates to a method of manufacturing a semiconductor device.

### BACKGROUND

For example, Patent Document 1 below discloses a technique for reducing dielectric constant of an interlayer insulating film by forming an air gap in the interlayer insulating film of a semiconductor device having a multilayer structure. In this technique, when the interlayer insulating film fills a recess on a substrate, by forming a space (void) that is defective in filling in the recess, the formed void is used as the air gap.

### PRIOR ART DOCUMENT

[Patent document]

Patent Document 1: Japanese Laid-open Publication No. 2012-54307

### SUMMARY

According to one embodiment of the present disclosure, a method of manufacturing a semiconductor device includes a first deposition process, a second deposition process, an oxidation process, and a desorption process. In the first deposition process, a thermally decomposable organic material on a substrate in which a recess is formed, is deposited. In the second deposition process, a metal layer is deposited on the organic material by sputtering, which uses a target containing metal. In the oxidation process, the metal layer is oxidized. In the desorption process, an air gap is formed between the oxidized metal layer and the recess by heating the substrate at a predetermined temperature to thermally decompose the organic material to desorb the organic material under the oxidized metal layer through the oxidized metal layer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a system configuration diagram illustrating an example of a manufacturing system according to an embodiment of the present disclosure.

FIG. 2 depicts a schematic cross section illustrating an example of a first deposition device according to an embodiment of the present disclosure.

FIG. 3 shows a schematic cross section illustrating an example of a second deposition device according to an embodiment of the present disclosure.

FIG. 4 depicts a schematic cross section illustrating an example of an oxidation device according to an embodiment of the present disclosure.

FIG. 5 shows a schematic cross section illustrating an example of an annealing device according to an embodiment of the present disclosure.

FIG. 6 is a flowchart showing an example of a method of manufacturing a semiconductor device.

FIG. 7 shows a schematic view illustrating an example of a process of manufacturing a semiconductor device.

FIG. 8 shows a schematic view illustrating an example of a process of manufacturing a semiconductor device.

FIG. 9 shows a schematic view illustrating an example of a process of manufacturing a semiconductor device.

FIG. 10 shows a schematic view illustrating an example of a process of manufacturing a semiconductor device.

FIG. 11 shows a schematic view illustrating an example of a process of manufacturing a semiconductor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An embodiment of a method of manufacturing a semiconductor device will now be described in detail with reference to the drawings. Further, the disclosed method of manufacturing a semiconductor device is not limited to the following embodiment.

By the way, the shape and size of a void, which is formed as a filling defect, depend on a width, a depth, or the like of a recess. For example, when the width of the recess is small, a large void is formed at a lower portion of the recess, but when the width of the recess is large, almost no void is formed at the lower portion of the recess. Further, the shape and size of the void formed in the recess may vary depending on a location of the recess on a substrate or a location of the recess in a semiconductor manufacturing apparatus. Thus, it is difficult to form a void having a desired shape and size with the recess having an arbitrary shape.

Therefore, a thermally decomposable organic material is deposited on the recess of the substrate, a sealing layer is deposited on the organic material, and then the substrate is heated to allow the thermally decomposed organic material to be desorbed from the recess via the sealing layer. Thus, an air gap having a shape corresponding to a shape of the organic material can be formed between the recess and the sealing layer. Such a sealing layer is formed by, for example, a layer-forming process using plasma.

However, if the surface of the organic material is exposed to the plasma when the sealing layer is formed, a portion of the organic material may be changed to a substance that is difficult to be thermally decomposed even when heated. Thus, even if the heating treatment is performed, the substance that is difficult to be thermally decomposed remains in the recess as a residue, making it difficult to form an air gap having a predetermined shape between the recess and the sealing layer.

Therefore, the present disclosure provides a technique of forming an air gap of a predetermined shape.

### [Configuration of the Manufacturing System 10]

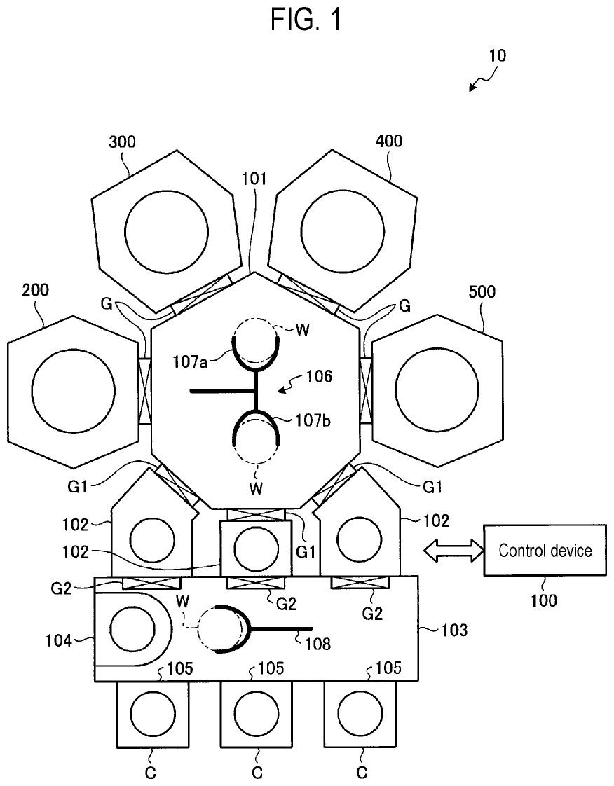

FIG. 1 is a system configuration diagram illustrating an example of a manufacturing system 10 according to an embodiment of the present disclosure. The manufacturing system 10 includes a first deposition device 200, a second deposition device 300, an oxidization device 400, and an annealing device 500. The manufacturing system 10 is a multi-chamber type vacuum processing system. By using the first deposition device 200, the second deposition device 300, the oxidization device 400, and the annealing device 500, the manufacturing system 10 forms an air gap in a substrate W where an element to be used for a semiconductor device is formed.

The first deposition device 200 deposits a layer of a thermally decomposable organic material on a surface of the substrate W on which a recess is formed. In the present embodiment, the thermally decomposable organic material is a polymer having urea bonds formed by polymerizing different types of monomers. The second deposition device 300 deposits a metal layer on the organic material, which has been deposited in the recess of the substrate W, by sputtering. The oxidization device 400 oxidizes the metal layer deposited by the second deposition device 300. The annealing device 500, by applying heat to the substrate W on which the metal layer oxidized by the oxidization device 400 is laminated, thermally decomposes the organic material under the oxidized metal layer, thereby desorbing the organic material through the oxidized metal layer. As a result, an air gap is formed between the recess of the substrate W and the oxidized metal layer.

The first deposition device 200, the second deposition device 300, the oxidization device 400, and the annealing device 500, each with a respective gate valve G, are connected to four sidewalls of a vacuum transport chamber 101 having a heptagonal planar shape. Three load-lock chambers 102 are respectively connected to the other three sidewalls of the vacuum transport chamber 101 via gate valves G1. Each of the three load-lock chambers 102 is connected to an atmosphere transport chamber 103 via a gate valve G2.

The inside of the vacuum transport chamber 101 is exhausted by a vacuum pump to be maintained at a predetermined degree of vacuum. A transport mechanism 106, such as a robot arm or the like, is provided in the vacuum transport chamber 101. The transport mechanism 106 transports the substrate W among the first deposition device 200, the second deposition device 300, the oxidization device 400, the annealing device 500, and each of the load-lock chambers 102. The transport mechanism 106 has two arms 107a and 107b which can move independently.

A plurality of ports 105 for accommodating carriers C (front-opening unified pod (FOUP) or the like) which hold substrates W are provided on a side surface of the atmosphere transport chamber 103. In addition, an alignment chamber 104 for aligning the substrates W is provided on a sidewall of the atmosphere transport chamber 103. A downflow of clean air is formed in the atmosphere transport chamber 103.

A transport mechanism 108, such as a robot arm or the like, is provided in the atmosphere transport chamber 103. The transport mechanism 108 transports a substrate W among each carrier C, each load-lock chamber 102, and the alignment chamber 104.

A control device 100 has a memory, a processor, and an input/output interface. A program executed by the processor, a recipe including conditions for each process, or the like is stored in the memory. The processor controls each part of the manufacturing system 10 via the input/output interface by executing the program retrieved from the memory based on the recipe stored in the memory.

### [First Deposition Device 200]

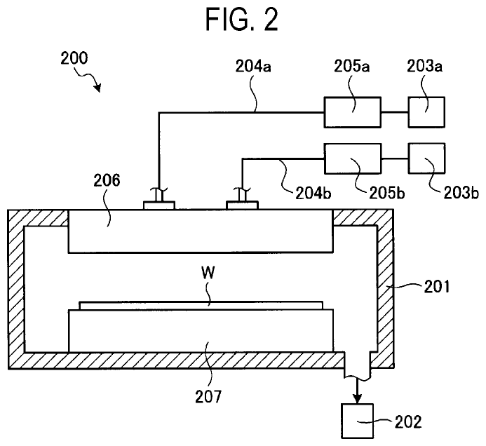

FIG. 2 depicts a schematic cross section illustrating an example of the first deposition device 200 according to an embodiment of the present disclosure. The first deposition device 200 has a vessel 201, an exhaust device 202, a shower head 206, and a mounting table 207. In the present embodiment, the first deposition device 200 is, for example, a chemical vapor deposition (CVD) device.

The exhaust device 202 exhausts a gas in the vessel 201. The inside of the vessel 201 is controlled by the exhaust device 202 to vacuum atmosphere of a predetermined pressure.

Multiple types of raw material monomers are supplied to the vessel 201. The multiple types of raw material monomers are, for example, isocyanate and amine A raw material supply source 203a for storing isocyanate in liquid is connected to the vessel 201 via a supply pipe 204a. In addition, a raw material supply source 203b for storing amine in liquid is connected to the vessel 201 via a supply pipe 204b.

The liquid of isocyanate supplied from the raw material supply source 203a is vaporized by a vaporizer 205a disposed in the supply pipe 204a. Then, the vapor of isocyanate is introduced into the shower head 206, which is a gas discharge unit, via the supply pipe 204a. Further, the liquid of amine supplied from the raw material supply source 203b is vaporized by a vaporizer 205b disposed in the supply pipe 204b. Then, the vapor of amine is introduced into the shower head 206.

For example, the shower head 206 is provided at the upper portion of the vessel 201, and has a plurality of discharge holes formed on the lower surface. The shower head 206 discharges the vapor of isocyanate and the vapor of amine introduced via the supply pipe 204a and the supply pipe 204b into the vessel 201 in a shower form from separate discharge holes, respectively.

The mounting table 207 having a temperature adjustment mechanism (not shown) is provided in the vessel 201. A substrate W on which a recess is formed on its surface is mounted on the mounting table 207. The mounting table 207 controls the temperature of the substrate W so that the temperature becomes suitable by the temperature adjustment mechanism for vapor deposition polymerization of the raw material monomers supplied from the raw material supply source 203a and the raw material supply source 203b, respectively. The temperature suitable for the vapor deposition polymerization may be determined according to the type of the raw material monomers, and may be set to, for example, 40 to 150 degrees C.

By allowing a vapor deposition polymerization reaction of the two types of raw material monomers to occur on the surface of the substrate W using such first deposition device 200, the organic material is deposited on the surface of the substrate W on which the recess has been formed. When the two types of raw material monomers are isocyanate and amine, a layer of polyurea polymer is deposited on the surface of the substrate W. The polyurea polymer is an example of a thermally decomposable organic material.

### [Second Deposition Device 300]

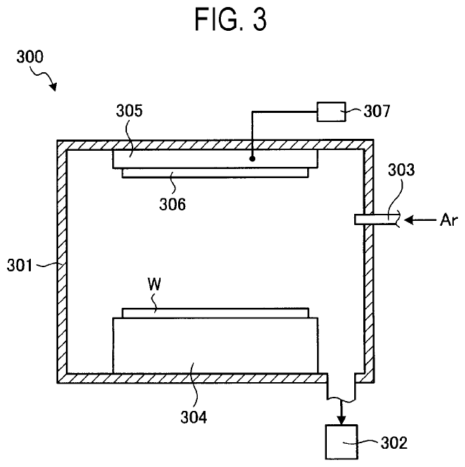

FIG. 3 shows a schematic cross section illustrating an example of the second deposition device 300 according to an embodiment of the present disclosure. The second deposition device 300 has a vessel 301, an exhaust device 302, a supply pipe 303, a mounting table 304, and a target holder 305. In the present embodiment, the second deposition device 300 is a sputtering device.

The exhaust device 302 exhausts a gas in the vessel 301. The inside of the vessel 301 is controlled by the exhaust device 302 to a vacuum atmosphere of a predetermined pressure.

An inert gas such as a noble gas or the like is supplied into the vessel 301 via the supply pipe 303. In the present embodiment, the inert gas is, for example, an Ar gas.

The mounting table 304 on which the substrate W is mounted is provided in the vessel 301. The mounting table 304 is provided with an electrostatic chuck (not shown), and the substrate W may be held by the electrostatic chuck. Further, by rotating during a layer-forming process, the mounting table 304 may rotate the substrate W about the central axis of the substrate W.

The target holder 305 is provided above the mounting table 304. On a lower surface, the target holder 305 holds a target 306 containing metal to be deposited on the substrate W so as to face the substrate W mounted on the mounting table 304. In the present embodiment, the metal deposited on the substrate W is, for example, aluminum. Also, the metal deposited on the substrate W may be another metal such as molybdenum, titanium, or tungsten.

A power source 307 is connected to the target holder 305. In the present embodiment, the power source 307 is a direct current (DC) power source that supplies a DC voltage to the target holder 305. In another embodiment, the power source 307 may be a radio frequency (RF) power source that supplies RF signals to the target holder 305.

In the second deposition device 300 illustrated in FIG. 3, while the substrate W is mounted on the mounting table 304, an Ar gas is supplied into the vessel 301 via the supply pipe 303 and the gas in the vessel 301 is exhausted by the exhaust device 302 such that the inside of the vessel 301 is adjusted to a predetermined degree of vacuum. Then, plasma is generated near the target 306 as a result of supplying a predetermined voltage from the power source 307 to the target 306 via the target holder 305, and ions contained in the plasma are drawn into the target 306.

Then, as the ions collide with the target 306, metal atoms contained in the target 306 are released from the target 306 and deposited onto the substrate W. Thus, a metal layer containing the metal contained in the target 306 is formed on the organic material deposited in the recess formed on the surface of the substrate W.

In the present embodiment, the deposition of the metal layer by the second deposition device 300 is performed, for example, when the temperature of the substrate W is a room temperature (25 degrees C.). Further, when the temperature of the substrate W is 200 degrees C. or lower, the deposition of the metal layer by the second deposition device 300 may be performed when the temperature of the substrate W is at a different temperature.

### [Oxidization Device 400]

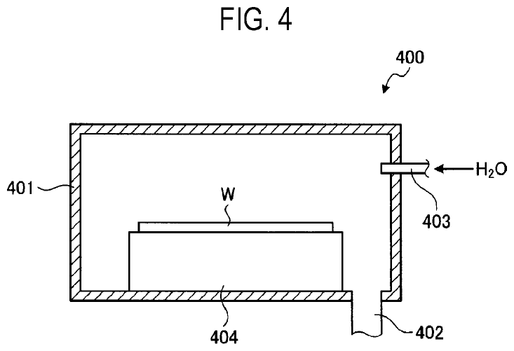

FIG. 4 shows a schematic cross section illustrating an example of the oxidization device 400 according to an embodiment of the present disclosure. The oxidization device 400 has a vessel 401, an exhaust pipe 402, a supply pipe 403, and a mounting table 404.

A gas in the vessel 401 is exhausted from the exhaust pipe 402. In the present embodiment, the inside of the vessel 401 is in a normal pressure atmosphere, but in another embodiment, the inside of the vessel 401 may be in a vacuum atmosphere.

An oxidizing gas is supplied into the vessel 401 via the supply pipe 403. In the present embodiment, the oxidizing gas is, for example, an H₂O gas. Also, the oxidizing gas may be an H₂O₂ gas, an O₂ gas, an O₃ gas, or the like.

The mounting table 404 on which the substrate W is mounted is provided in the vessel 401. The mounting table 404 is provided with an electrostatic chuck (not shown), and the substrate W may be held by the electrostatic chuck. The metal layer formed on the surface of the substrate W mounted on the mounting table 404 is oxidized by the oxidizing gas supplied into the vessel 401. In the present embodiment, since the aluminum layer is formed on the surface of the substrate W, the aluminum layer formed on the surface of the substrate W is oxidized by the oxidization device 400 to become an aluminum oxide layer.

In the present embodiment, the process of oxidizing the metal layer by the oxidization device 400 is performed, for example, when the temperature of the substrate W is a room temperature (e.g., 25 degrees C.). Further, when the temperature of the substrate W is 200 degrees C. or lower, the process of oxidizing the metal layer by the oxidization device 400 may be performed when the temperature of the substrate W is at a different temperature.

### [Annealing Device 500]

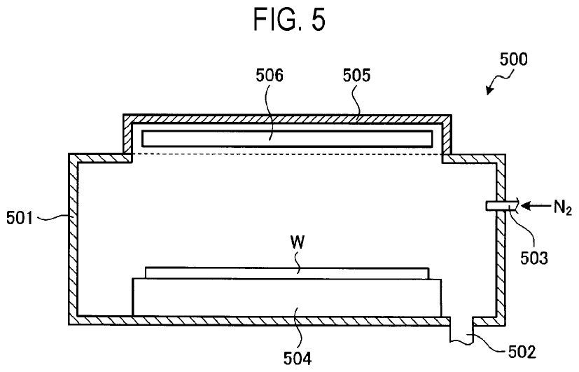

FIG. 5 depicts a schematic cross section illustrating an example of the annealing device 500 according to an embodiment of the present disclosure. The annealing device 500 has a vessel 501, an exhaust pipe 502, a supply pipe 503, a mounting table 504, a lamp house 505, and an infrared lamp 506.

The mounting table 504 on which the substrate W is mounted is provided in the vessel 501. The lamp house 505 is provided at a location facing the surface of the mounting table 504 on which the substrate W is mounted. The infrared lamp 506 is disposed in the lamp house 505.

An inert gas is supplied into the vessel 501 via the supply pipe 503. In the present embodiment, the inert gas is, for example, an N₂ gas.

The inert gas is supplied into the vessel 501 via the supply pipe 503, with the substrate W mounted on the mounting table 504. Then, the substrate W is heated by turning on the infrared lamp 506. When the organic material deposited in the recess of the substrate W reaches a predetermined temperature, the organic material is thermally decomposed into two types of raw material monomers. In the present embodiment, since the organic material is polyurea, as the substrate W is heated to 300 degrees C. or higher, for example, at 500 degrees C., the organic material is depolymerized into isocyanate and amine, which are raw material monomers.

Further, the isocyanate and amine generated by the depolymerization pass through the oxidized metal layer deposited on the organic material such that the organic material of the recess of the substrate W is desorbed. Thus, an air gap is formed between the recess of the substrate W and the oxidized metal layer.

### [Method of Forming an Air Gap]

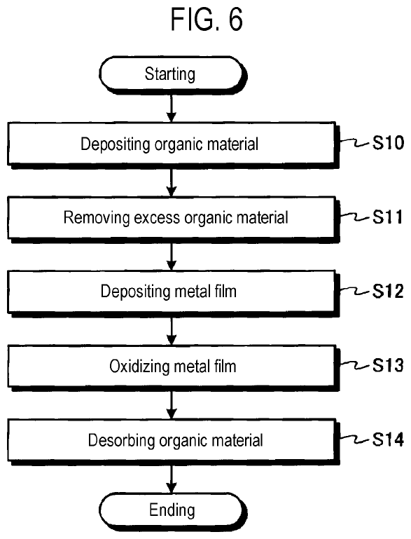

FIG. 6 is a flowchart showing an example of a method of manufacturing a semiconductor device. For example, when a substrate W on which a recess is formed is loaded into the first deposition device 200, a process illustrated in FIG. 6 is started.

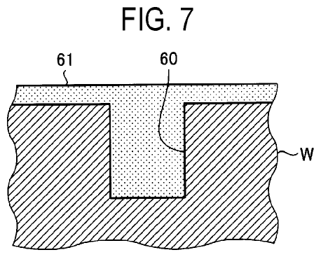

First, a thermally decomposable organic material is deposited on the substrate W by the first deposition device 200 (S10). Step S10 is an example of a first deposition process. Thus, as illustrated in FIG. 7, for example, an organic material 61 is deposited in a recess 60 of the substrate W. Then, the substrate W is unloaded from the first deposition device 200 by the transport mechanism 106 and loaded into the annealing device 500.

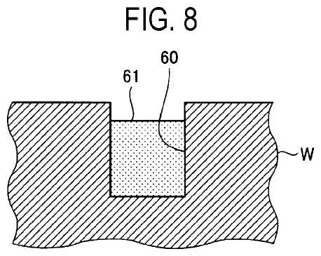

Next, the substrate W is heated by the annealing device 500 such that an excess organic material deposited on the substrate W is removed (S11). In step S11, the substrate W is heated by the annealing device 500 to, for example, 200 to 300 degrees C. Thus, as illustrated in FIG. 8, for example, a portion of the organic material 61, which has been deposited on an upper surface of the substrate W, is desorbed by thermal decomposition. Then, the substrate W is unloaded from the annealing device 500 by the transport mechanism 106 and loaded into the second deposition device 300.

Next, a metal layer is deposited on the substrate W by the second deposition device 300 (S12). Step S12 is an example of a second deposition process. In step S12, the metal layer is deposited on the organic material by sputtering that uses a target containing metal. In the present embodiment, the target includes aluminum. The main layer-forming conditions for sputtering the metal layer at step S12 may be, for example, as follows.

Temperature of substrate W: room temperature (25 degrees C.)

Ar gas flow rate: 10 sccm

Internal pressure of the vessel 301: 10 Pa

Electric power supplied to the target 306: 200 W

Further, the flow rate of the Ar gas may be a flow rate which falls within a range of, for example, 5 to 50 sccm. In addition, the internal pressure of the vessel 301 may be a pressure which falls within a range of, for example, 5 to 20 Pa. The power supplied to the target 306 may be an electric power which falls within a range of, for example, 100 to 500 W.

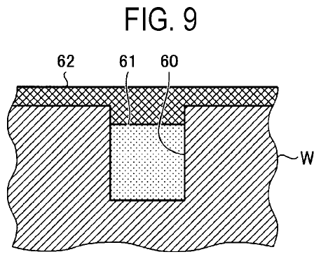

Thus, for example, as illustrated in FIG. 9, a metal layer 62 is deposited on the organic material 61 in the recess 60 of the substrate W. Then, the substrate W is unloaded from the second deposition device 300 by the transport mechanism 106 and loaded into the oxidation device 400.

Next, the metal layer 62 deposited on the substrate W is oxidized by the oxidization device 400 (S13). Step S13 is an example of an oxidization process. The oxidization process at step S13 is performed when the temperature of the substrate W is a room temperature.

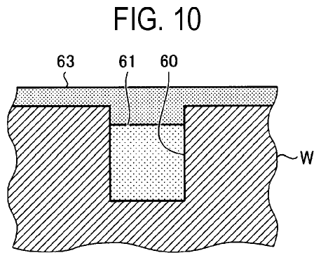

Thus, for example, as illustrated in FIG. 10, the metal layer 62 deposited on the organic material 61, which is in the recess 60 of the substrate W, is oxidized to become an oxidized metal layer 63. Then, the substrate W is unloaded from the oxidization device 400 by the transport mechanism 106 and again loaded into the annealing device 500.

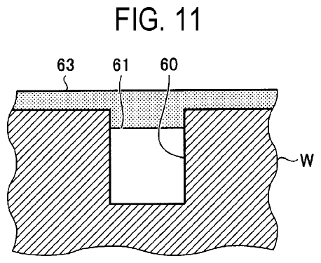

Next, the substrate W is heated by the annealing device 500 so that the organic material 61 in the recess 60 is desorbed (S14). Step S14 is an example of a desorption process. In step S14, the substrate W is heated by the annealing device 500 to, for example, 300 degrees C. or higher. Thus, for example, as illustrated in FIG. 11, the organic material 61, which is between the oxidized metal layer 63 and the recess 60 is desorbed via the oxidized metal layer 63, to form an air gap having a shape corresponding to the shape of the organic material 61 between the oxidized metal layer 63 and the recess 60. Then, the process illustrated in this flowchart is ended.

In the present embodiment, after the metal layer is deposited on the organic material in the recess of the substrate W, the metal layer is oxidized to form a path in the metal layer, through which the gas of the thermally decomposed monomer escapes. Accordingly, in the present embodiment, a sealing layer having a path through which the gas of the thermally decomposed monomer escapes, and also having high physical strength, can be formed without using plasma on the organic material in the recess.

Further, in an experiment where gold was used to form a metal layer on the organic material and where the organic material was subsequently thermally decomposed, the organic material remained in the recess without passing through the metal layer. On the other hand, in an experiment where aluminum oxide was used to form an oxidized metal layer on the organic material and where the organic material was subsequently thermally decomposed, an air gap was formed by the organic material, which passed through the metal layer and was removed from the recess. According to this experiment, it is also evident that because the metal layer deposited on the organic material is oxidized, a path through which the gas of the thermally decomposed monomer escapes is formed on the metal layer.

The embodiment has been described above. As described above, the method of manufacturing a semiconductor device according to the present embodiment includes the first deposition process, the second deposition process, the oxidization process, and the desorption process. At the first deposition process, the thermally decomposable organic material 61 is deposited on the substrate W on which the recess 60 is formed. At the second deposition process, the metal layer 62 is deposited on the organic material 61 by sputtering using a target containing metal. At the oxidization process, the metal layer 62 is oxidized. At the desorption process, the organic material 61 under the oxidized metal layer 63 is desorbed via the oxidized metal layer 63 by heating the substrate W to a predetermined temperature to thermally decompose the organic material 61 such that an air gap can be formed between the oxidized metal layer 63 and the recess 60. Thus, an air gap having a predetermined shape can be formed.

Further, in the aforementioned embodiment, at the second deposition process, sputtering is performed using a target containing aluminum, molybdenum, titanium, tungsten, or the like. Thus, a sealing layer having a path through which the gas of the thermally decomposed monomer escapes can be formed on the organic material.

Moreover, in the aforementioned embodiment, the second deposition process and the oxidization process are performed when the temperature of the substrate W is maintained at 200 degrees C. or lower. As a result, an air gap having a predetermined shape can be formed.

### [Others]

The technique disclosed herein is not limited to the aforementioned embodiment but many modifications may be made without departing from the spirit of the present disclosure.

For example, in the aforementioned embodiment, the oxidized metal layer is formed on the organic material deposited in the recess of the substrate W, by oxidizing the metal layer after the metal layer is deposited, but the disclosed technique is not limited thereto. For example, in the second deposition process, the metal oxide layer may be deposited on the organic material by sputtering, which uses a target containing metal oxide. Thus, the oxidization process becomes unnecessary, thereby reducing the time required for forming the air gap.

Further, when the metal oxide layer is deposited on the organic material by sputtering, which uses a target containing metal oxide, a target containing aluminum oxide, molybdenum oxide, titanium oxide, tungsten oxide, or the like is used as the target. Thus, a sealing layer having a path through which the thermally decomposed monomer in the form of a gas escapes can be formed on the organic material.

In addition, even when the metal oxide layer is deposited on the organic material by sputtering, which uses a target containing metal oxide, the second deposition process is performed when the temperature of the substrate W is maintained at 200 degrees C. or lower (for example, a room temperature (25 degrees C.). Thus, an air gap having a predetermined shape can be formed.

Moreover, in another embodiment, at the second deposition process, the metal oxide layer may be deposited on the organic material by performing sputtering, which uses a target containing metal in an oxygen-containing gas atmosphere. In this case also, the oxidization process becomes unnecessary, thereby reducing the time required for forming the air gap.

Furthermore, in each of the aforementioned embodiments, the polymer having urea bonds was used as an example of the polymer constituting the organic material, but as the polymer constituting the organic material, a polymer having bonds other than the urea bonds may be used. Examples of the polymer having bonds other than the urea bonds may include polyurethane and the like having urethane bonds. For example, polyurethane may be synthesized by copolymerizing a monomer having an alcohol group and a monomer having an isocyanate group. Further, by being heated to a predetermined temperature, the polyurethane is depolymerized into a monomer having an alcohol group and a monomer having an isocyanate group.

According to the various aspects and embodiments of the present disclosure, it is possible to form an air gap having a predetermined shape.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device comprising:
depositing a thermally decomposable organic material on a substrate in which a recess is formed;
depositing a metal layer on the organic material by sputtering, which uses a target containing metal;
oxidizing the metal layer; and
forming an air gap between the oxidized metal layer and the recess by heating the substrate at a predetermined temperature to thermally decompose the organic material to desorb the organic material under the oxidized metal layer through the oxidized metal layer.

2. The method of claim 1, wherein depositing the metal layer comprises performing the sputtering using the target containing aluminum, molybdenum, titanium, or tungsten.

3. The method of claim 2, wherein depositing the metal layer and oxidizing the metal layer are performed while the substrate is maintained at a temperature of 200 degrees C. or lower.

4. The method of claim 1, wherein depositing the metal layer and oxidizing the metal layer are performed while the substrate is maintained at a temperature of 200 degrees C. or lower.

5. A method of manufacturing a semiconductor device, comprising:
depositing a thermally decomposable organic material on a substrate in which a recess is formed;
depositing a metal oxide layer on the organic material by sputtering, which uses a target containing metal oxide; and
forming an air gap between the metal oxide layer and the recess by heating the substrate at a predetermined temperature to thermally decompose the organic material to desorb the organic material under the metal oxide layer through the metal oxide layer.

6. The method of claim 5, wherein depositing the metal layer comprises performing the sputtering using the target containing aluminum oxide, molybdenum oxide, titanium oxide, or tungsten oxide.

7. The method of claim 6, wherein depositing the metal oxide layer is performed while the substrate is maintained at a temperature of 200 degrees C. or lower.

8. The method of claim 5, wherein depositing the metal oxide layer is performed while the substrate is maintained at a temperature of 200 degrees C. or lower.
